(19) United States
(12) Patent Application Publication
(10) Pub. No.: US 2014/0083751 A1
(43) Pub. Date: Mar. 27, 2014

(54) TOUCH PANEL

(71) Applicant: SAMSUNG ELECTRO-MECHANICS CO., LTD., Suwon (KR)

(72) Inventors: Sang Hwan Oh, Suwon (KR); Youn Soo Kim, Suwon (KR); Ho Joon Park, Suwon (KR)

(73) Assignee: SAMSUNG ELECTRO-MECHANICS CO., LTD., Suwon (KR)

(21) Appl. No.: 13/731,425

(22) Filed: Dec. 31, 2012

(30) Foreign Application Priority Data
Sep. 21, 2012 (KR) 10-2012-0105393

(51) Int. Cl. H05K 1/02; H05K 1/09

(52) U.S. Cl. CPC H05K 1/02; H05K 1/09
USPC 174/257; 174/250

(57) ABSTRACT

Disclosed herein is a touch panel. The touch panel 100 according to a preferred embodiment of the present invention includes an electrode pattern 110 formed of a combination of unit patterns 113 in which an intersecting region 117 in which sides 115 intersect each other and a width of the side 115 in the intersecting region 117 is smaller than a width of the side 115 outside the intersecting region 117.

### CROSS REFERENCE TO RELATED APPLICATION

This application claims the benefit of Korean Patent Application No. 10-2012-0105393, filed on Sep. 21, 2012, entitled “Touch Panel”, which is hereby incorporated by reference in its entirety into this application.

### BACKGROUND OF THE INVENTION

1. Technical Field

The present invention relates to a touch panel.

2. Description of the Related Art

In accordance with the growth of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has widened the use of computers more and more, it is difficult to efficiently operate products using only a keyboard and a mouse currently serving as an input device. Therefore, the necessity for a device that is simple, has minimum malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of a display such as an electronic organizer, a flat panel display device including a liquid crystal display (LCD) device, a plasma display panel (PDP), an electroluminescence (El) element, or the like, and a cathode ray tube (CRT) to thereby be used to allow a user to select desired information while viewing the display.

In addition, the touch panel is classified into a resistive type, a capacitive type, an electromagnetic type, a surface acoustic wave (SAW) type, and an infrared type. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

Meanwhile, as the touch panel described in the following Patent Document described in the following Prior Art Document, researches for forming electrode patterns using metals have been actively conducted. As described above, when the electrode pattern is formed of metals, there are advantages in that electric conductivity is excellent and a demand and supply is smooth. However, when the electrode pattern is formed metals, the electrode pattern needs to be formed to have a mesh structure in a micrometer (μm) unit so as to prevent the electrode pattern from being recognized by a user. However, the mesh structure does not intersect vertically and therefore, a width of an intersecting region is larger than that of other regions, such that there is a problem in that the intersecting region is recognized by a user.

### PRIOR ART DOCUMENT

### Patent Document

(Patent Document 1) JP2011-175967 A

### SUMMARY OF THE INVENTION

The present invention has been made in an effort to provide a touch panel capable of preventing an intersecting region from being formed wider than other regions other than the intersecting region, by making a width of a side small in the intersecting region of electrode patterns.

According to a preferred embodiment of the present invention, there is provided a touch panel including: an electrode pattern formed of a combination of unit patterns in which an intersecting region in which sides intersect each other is formed and a width of the side in the intersecting region is smaller than a width of a side outside the intersecting region.

The sides may intersect each other at an angle more or less than 90°.

The unit pattern may be a diamond shape.

The width of the side outside the intersecting region may be constant.

The touch panel may further include: a transparent substrate on which the electrode pattern is formed.

The electrode pattern may be formed of copper (Cu), aluminum (Al), gold (Au), silver (Ag), titanium (Ti), palladium (Pd), and chromium (Cr), or a combination thereof.

The electrode pattern may be formed of metal silver formed by exposing/developing a silver salt emulsion layer.

According to another preferred embodiment of the present invention, there is provided a touch panel including: an electrode pattern formed of a combination of unit patterns in which an intersecting region in which sides intersect each other is formed and a width of the side is reduced toward the intersecting region.

The sides may intersect each other at an angle more or less than 90°.

The unit pattern may be a diamond shape.

The width of the side may be reduced step-by-step toward the intersecting region.

The touch panel may further include: a transparent substrate on which the electrode pattern is formed.

The electrode pattern may be formed of copper (Cu), aluminum (Al), gold (Au), silver (Ag), titanium (Ti), palladium (Pd), and chromium (Cr), or a combination thereof.

The electrode pattern may be formed of metal silver formed by exposing/developing a silver salt emulsion layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view of a touch panel according to a first preferred embodiment of the present invention;

FIG. 2 is an enlarged plan view of an X portion of FIG. 1;

FIG. 3 is a plan view illustrating a comparison example of the touch panel according to the preferred embodiment of the present invention;

FIGS. 4 to 6 are cross-sectional views of the touch panel according to the first preferred embodiment of the present invention;

FIGS. 7 and 8 are plan views of a touch panel according to a second preferred embodiment of the present invention;

FIG. 9 is an enlarged plan view of a Y portion of FIG. 7; and

FIG. 10 is an enlarged plan view of a Z portion of FIG. 8.

### DESCRIPTION OF THE PREFERRED EMBODIMENTS

The above and other objects, features and advantages of the present invention will be more clearly understood from preferred embodiments and the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, preferred embodiments of the present invention will be described in detail with reference to the accompanying drawings.

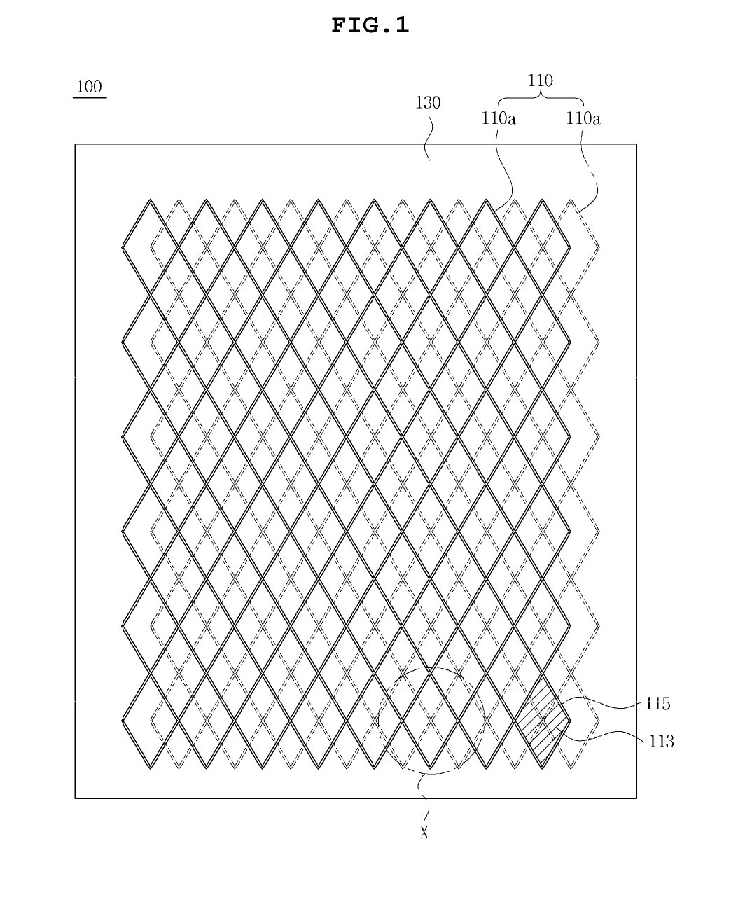

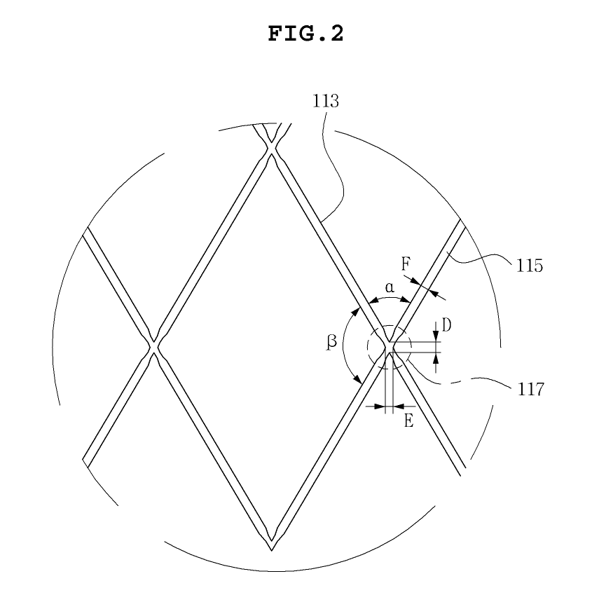

FIG. 1 is a plan view of a touch panel according to a first preferred embodiment of the present invention and FIG. 2 is an enlarged plan view of an X portion of FIG. 1.

As illustrated in FIGS. 1 and 2, a touch panel 100 according to a preferred embodiment of the present invention includes an electrode pattern 110 formed of a combination of unit patterns 113 in which an intersecting region 117 in which sides 115 intersect each other and a width of the side 115 in the intersecting region 117 is smaller than a width of the side 115 outside the intersecting region 117.

The electrode pattern 110 serves to generate a signal when being touched by a user to allow a controller to recognize touched coordinates. Here, the electrode pattern 110 may be formed to have a fine pattern in a micrometer (μm) unit using copper (Cu), aluminum (Al), gold (Au), silver (Ag), titanium (Ti), palladium (Pd), and chromium (Cr), or a combination thereof. Further, the electrode pattern 110 may include a first electrode pattern 110a and a second electrode pattern 110b. In this case, the first electrode pattern 110a and the second electrode pattern 110b may be formed on different layers. However, the electrode pattern 110 does not necessarily include two electrode patterns (first electrode pattern 110a and second electrode pattern 110b), but may be configured to include the single electrode pattern 110. Meanwhile, the electrode pattern 110 may be formed by a plating process or a deposition process using sputter. Further, when the electrode pattern 110 is formed of metals such as copper (Cu), and the like, the surface of the electrode pattern 110 may be black-oxide treated. Here, the black-oxide treating elutes Cu₂O or CuO by oxidizing the surface of the electrode pattern 110, wherein the Cu₂O has brown and therefore, is referred to as brown oxide and the CuO has black and therefore, is referred to as black oxide. As such, it is possible to prevent light from being reflected by black-oxide treating the surface of the electrode pattern 110, thereby improving the visibility of the touch panel 100. Meanwhile, in addition to the foregoing metals, the electrode pattern 110 may also be formed of metal silver formed by exposing/developing a silver salt emulsion layer.

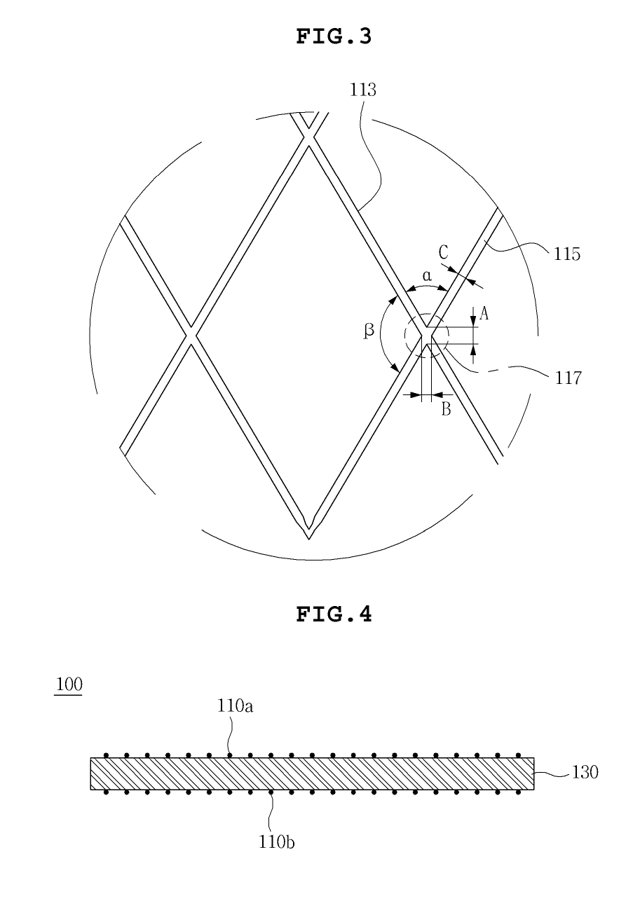

Further, as illustrated in FIG. 2, the electrode pattern 110 may be formed to have a mesh structure that is a combination of diamond-like unit patterns 113. Here, the sides of the unit pattern 113 may generally intersect each other at an angle more or less than 90°. That is, the sides 115 of the unit pattern 113 may intersect each other at an acute angle α or an obtuse angle β. As described above, when the sides 115 of the unit pattern 113 intersect each other at the acute angle α or the obtuse angle β, the width of the intersecting region 117 in which the sides 115 intersect each other may be larger than that of other regions other than the intersecting region 117. FIG. 3 is a plan view illustrating a comparison example of the touch panel according to the preferred embodiment of the present invention. The reason why the width of the intersecting region 117 is larger than that of other regions other than the intersecting region 117 will be described with reference to FIG. 3. In detail, when a vertical width A of the intersecting region 117, a horizontal width B of the intersecting region 117, and a width C of the side 115 compare with one another, the size of the vertical width A of the intersecting region 117, the horizontal width B of the intersecting region 117, and the width C of the side 115 is large in that order (A>B>C). In this case, since the vertical width A and the horizontal width B correspond to the width of the intersecting region 117 and the width C of the side 115 corresponds to a width of other regions other than the intersecting region 117, it can be confirmed that the width of the intersecting region 117 is larger than that of other regions other than the intersecting region 117. Therefore, it is highly likely for a user to recognize the intersecting region 117, as compared with other regions other than the intersecting region 117. However, as illustrated in FIG. 2, in the touch panel 110 according to the preferred embodiment of the present invention, the width of the side 115 in the intersecting region 117 is smaller than that of the side 115 outside the intersecting region 117 and therefore, it is possible to prevent the width of the intersecting region 117 from being formed larger than that of other regions other than the intersecting region 117. Actually, it can be confirmed that a vertical width D of the intersecting region 117, a horizontal width E of the intersecting region 117, and a width F of the side 115 outside the intersecting region 117 have an approximately similar size. Therefore, it is possible to prevent the intersecting region 117 from being recognized by a user. Meanwhile, in order to prevent a specific portion emerged outside the intersecting region 117 from being recognized by a user, a width F of the side 115 may be constant outside the intersecting region 117.

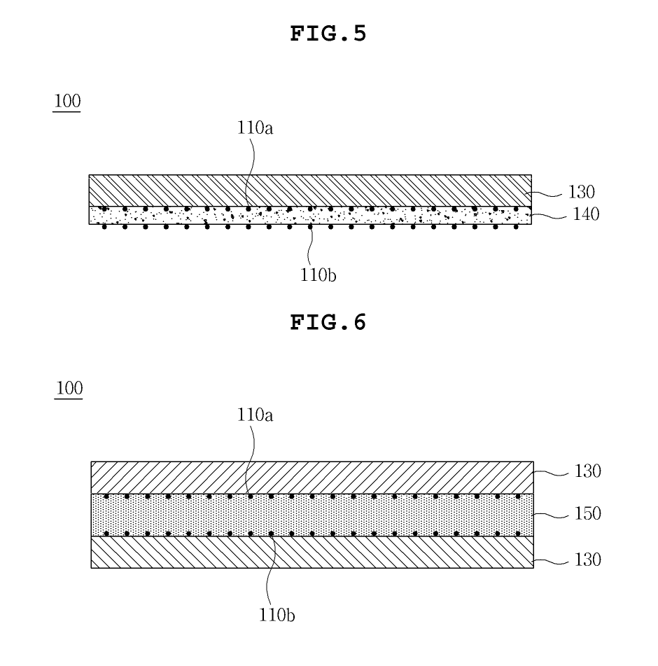

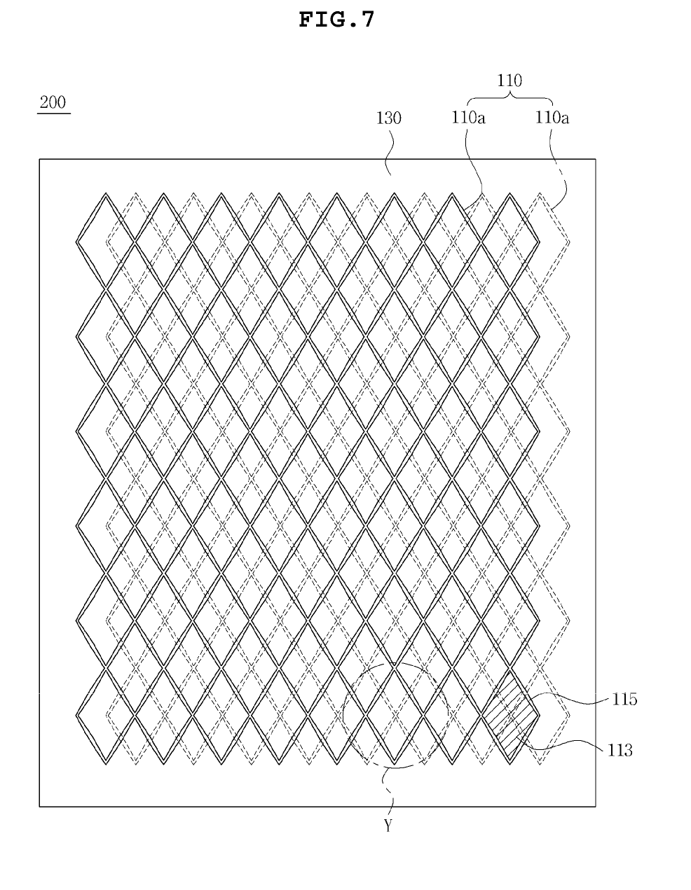

Further, FIGS. 4 to 6 are cross-sectional views of the touch panel according to the first preferred embodiment of the present invention. As illustrated in FIG. 4, the touch panel 100 according to the preferred embodiment of the present invention may include a transparent substrate 130 having the first electrode pattern 110a formed on one surface and the second electrode pattern 110b formed on the other surface. Here, the transparent substrate 130 provides an area in which the first and second electrode patterns 110a and 110b are formed. However, the first electrode pattern 110a and the second electrode pattern 110b are not necessarily formed on both surfaces of the single transparent substrate 130. That is, as illustrated in FIG. 5, after the first electrode pattern 110a is formed on the transparent substrate 130, an insulating layer 140 may be formed on the transparent substrate 130 and the second electrode pattern 110b may be formed on the insulating layer 140. In addition, as illustrated in FIG. 6, two transparent substrates 130 are provided, wherein the two transparent substrates 130 may each be provided with the first electrode pattern 110a and the second electrode pattern 110b. In this case, the two transparent substrates 130 may be bonded by an adhesive layer 150. Meanwhile, the transparent substrate 130 may be made of polyethylene terephthalate (PET), polycarbonate (PC), poly methyl methacrylate (PMMA), polyethylene naphthalate (PEN), polyethersulfone (PES), a cyclic olefin copolymer (COC), a triacetylcellulose (TAC) film, a polyvinyl alcohol (PVA) film, a polyimide (PI) film, polystyrene (PS), biaxially oriented polystyrene (BOPS; containing K resin), glass, or tempered glass, and the like, but are not necessarily limited thereto. Further, in order to improve the adhesion between the transparent substrate 130 and the electrode pattern 110, the transparent substrate 130 may be subjected to a high frequency treatment or a primer treatment.

In addition, an edge of the electrode pattern 110 is provided with an electrode wiring that transmits/receives an electrical signal from the electrode pattern 110. In this case, the electrode wiring 120 is integrally formed with the electrode pattern 110, thereby simplifying the manufacturing process and shortening the lead time. Further, the electrode wiring is integrally formed with the electrode pattern 110, thereby removing the bonding process between the electrode wiring and the electrode pattern 110 and preventing beforehand the occurrence of a step or the bonding defect between the electrode wiring and the electrode pattern 110.

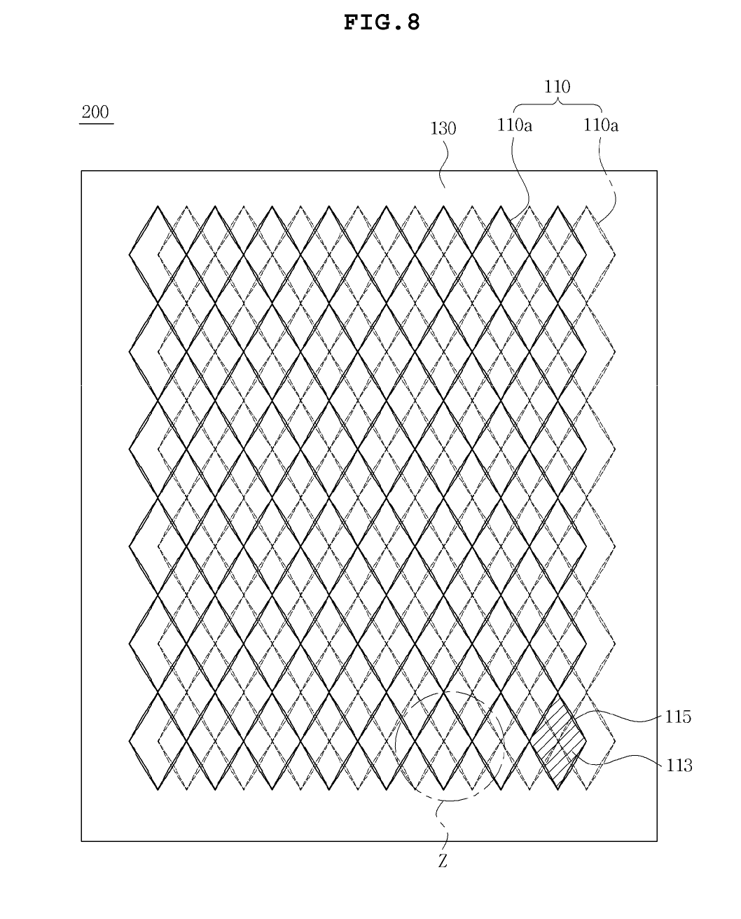

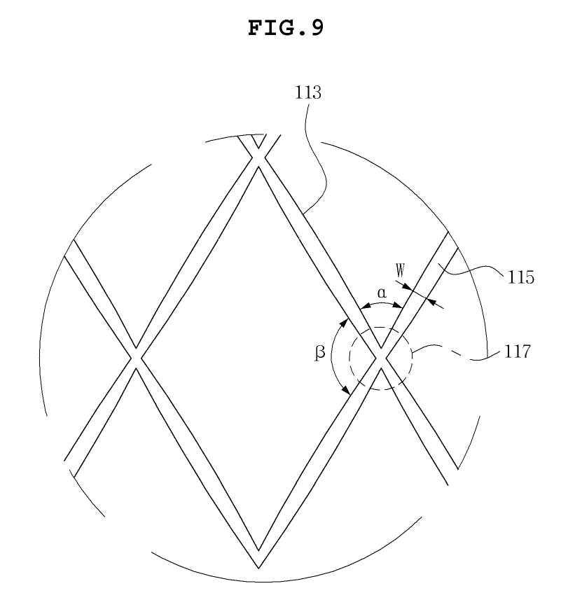

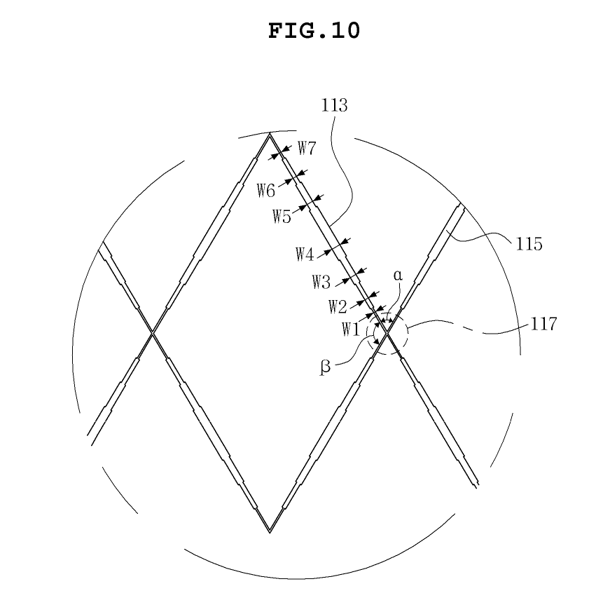

FIGS. 7 and 8 are plan views of a touch panel according to a second preferred embodiment of the present invention, FIG. 9 is an enlarged plan view of a Y portion of FIG. 7, and FIG. 10 is an enlarged plan view of a Z portion of FIG. 8.

As illustrated in FIGS. 7 to 10, a touch panel 200 according to a preferred embodiment of the present invention includes the electrode pattern 110 formed of a combination of the unit patterns 113 in which the intersecting region 117 in which the sides 115 intersect each other is formed and a width w of the side 115 is reduced toward the intersecting region 117. When the touch panel 200 according to the preferred embodiment of the present invention compares with the touch panel 100 according to the first preferred embodiment of the present invention, the touch panel 100 is different from the touch panel 100 in that the width w of the side 115 is reduced toward the intersecting region 117. Therefore, the overlapping contents with the touch panel 100 according to the first preferred embodiment of the present invention will be omitted and the fact that the width w of the side 115 is reduced toward the intersecting region 117 will be mainly described.

The electrode pattern 110 serves to generate a signal when being touched by a user to allow a controller to recognize touched coordinates. Here, the electrode pattern 110 may be formed to have a fine pattern in a micrometer (μm) unit and the electrode pattern 110 may include the first electrode pattern 110a and the second pattern 110b. Further, as illustrated in FIGS. 9 and 10, the electrode pattern 110 may be formed to have a mesh structure that is a combination of diamond-like unit patterns 113. Here, the sides 115 of the unit pattern 113 may generally intersect each other at an angle more or less than 90°. That is, the sides 115 of the unit pattern 113 may intersect each other at an acute angle α or an obtuse angle β. As described above, when the sides 115 of the unit pattern 113 intersect each other at the acute angle α or the obtuse angle β, as illustrated in FIG. 3, the width of the intersecting region 117 in which the sides 115 intersect each other may be larger than that of other regions other than the intersecting region 117. Therefore, it is highly likely for a user to recognize the intersecting region 117, as compared with other regions other than the intersecting region 117. However, in the touch panel 200 according to the preferred embodiment of the present invention, the width w of the side 115 is reduced toward the intersecting region 117 and therefore, it is possible to prevent the width of the intersecting region 117 from being formed larger than that of other regions other than the intersecting region 117. Therefore, it is possible to prevent the intersecting region 117 from being recognized by a user. Meanwhile, the width w of the side 115 may be continuously reduced toward the intersecting region 117 (see FIG. 9). In this case, a step does not occur at a boundary line of the sides 115 and a central portion thereof is formed to have a convex shape. However, the width of the side 115 is not necessarily reduced at a predetermined ratio. For example, the width w of the side 115 may be reduced step-by-step toward the intersecting region 117 (see FIG. 10). That is, the width of the side 115 may be changed in order of w1→w2→w3→w4→w5→w6→w7. In this case, the step occurs at the boundary line of the sides 115 at a predetermined interval and the central portion thereof is formed to have a convex shape.

According to the preferred embodiments of the present invention, it is possible to prevent the intersecting region from being recognized by a user by making the width of the side small in the intersecting region of the electrode patterns to prevent the intersecting region from being formed wider than other regions other than the intersecting region.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel, comprising:
an electrode pattern formed of a combination of unit patterns in which an intersecting region in which sides intersect each other is formed and a width of the side in the intersecting region is smaller than a width of a side outside the intersecting region.

2. The touch panel as set forth in claim 1, wherein the sides intersect each other at an angle more or less than 90°.

3. The touch panel as set forth in claim 1, wherein the unit pattern is a diamond shape.

4. The touch panel as set forth in claim 1, wherein the width of the side outside the intersecting region is constant.

5. The touch panel as set forth in claim 1, further comprising:
a transparent substrate on which the electrode pattern is formed.

6. The touch panel as set forth in claim 1, wherein the electrode pattern is formed of copper (Cu), aluminum (Al), gold (Au), silver (Ag), titanium (Ti), palladium (Pd), and chromium (Cr), or a combination thereof.

7. The touch panel as set forth in claim 1, wherein the electrode pattern is formed of metal silver formed by exposing/developing a silver salt emulsion layer.

8. A touch panel, comprising:
an electrode pattern formed of a combination of unit patterns in which an intersecting region in which sides intersect each other is formed and a width of the side is reduced toward the intersecting region.

9. The touch panel as set forth in claim 8, wherein the sides intersect each other at an angle more or less than 90°.

10. The touch panel as set forth in claim 8, wherein the unit pattern is a diamond shape.

11. The touch panel as set forth in claim 8, wherein the width of the side is reduced step-by-step toward the intersecting region.

12. The touch panel as set forth in claim 8, further comprising:
a transparent substrate on which the electrode pattern is formed.

13. The touch panel as set forth in claim 8, wherein the electrode pattern is formed of copper (Cu), aluminum (Al), gold (Au), silver (Ag), titanium (Ti), palladium (Pd), and chromium (Cr), or a combination thereof.

14. The touch panel as set forth in claim 8, wherein the electrode pattern is formed of metal silver formed by exposing/developing a silver salt emulsion layer.
